(19) United States
(12) Patent Application Publication
(10) Pub. No.: US 2026/0214852 A1
(43) Pub. Date: Jul. 23, 2026

(54) SYSTEMS AND METHODS FOR COOLING A HEAT-GENERATING DEVICE

(71) Applicant: Toyota Motor Engineering & Manufacturing North America, Inc., Plano, TX (US)

(72) Inventors: Shailesh N Joshi, Ann Arbor, MI (US); Danny J Lohan, West Bloomfield, MI (US); Feng Zhou, Ann Arbor, MI (US); Ercan M Dede, Ann Arbor, MI (US)

(73) Assignee: Toyota Motor Engineering & Manufacturing North America, Inc., Plano, TX (US)

(21) Appl. No.: 19/035,271

(22) Filed: Jan. 23, 2025

(51) Int. Cl. H05K 7/20

(52) U.S. Cl. CPC H05K 7/20327; H05K 7/20445

(57) ABSTRACT

Embodiments herein are directed to a cooling system that includes a heat-generating device and a cooler loop assembly. The cooler loop assembly includes a capillary loop thermally coupled to the heat-generating device, a pump loop, and a secondary loop. The pump loop is fluidly coupled to the capillary loop. A pump is configured to move a cooling fluid through the pump loop and the capillary loop to cool the heat-generating device. A vaporized cooling fluid generated by the cooling of the heat-generating device is vented. The secondary loop has a liquid jet ejector pump. The secondary loop is fluidly coupled to the capillary loop such that the vaporized cooling fluid vented by the capillary loop is received by the liquid jet ejector pump. The vaporized cooling fluid is combined with the cooling fluid within the liquid jet ejector pump to circulate the cooling fluid through the secondary loop.

### TECHNICAL FIELD

The present disclosure is directed to cooling assemblies for controlling a flow of a cooling fluid, and more particularly, to auxiliary cooler loop assemblies that passively cool heat-generating devices.

### BACKGROUND

Batteries, such as those used for electric vehicles, may generate significant heat during operation, which requires cooling in order to keep the batteries within their optimal operating temperature range. Conventional cooling systems can involve passing a cooling fluid along a battery cover to cool the battery core and maintain the battery core within its optimal operating temperature range. The cooling fluid may be pumped around the various components. Conventional systems utilize a pump to drive the cooling fluid. However, due to increase cooling needs, pump loads have greatly increased. As such, a need exists for driving a cooling fluid to cool heat-generating components while reducing a pump load of the pump of the cooling assembly.

### SUMMARY

According to one embodiment, a cooling system is provided. The cooling system includes a heat-generating device and a cooler loop assembly. The cooler loop assembly includes at least one capillary loop thermally coupled to the heat-generating device, a pump loop, and a secondary loop. The pump loop has a pump. The pump loop is fluidly coupled to the at least one capillary loop. The pump is configured to move a cooling fluid through the pump loop and at least one capillary loop to cool the heat-generating device. A vaporized cooling fluid generated by the cooling of the heat-generating device is vented by at least one capillary loop. The secondary loop has a liquid jet ejector pump. The secondary loop is fluidly coupled to the at least one capillary loop such that the vaporized cooling fluid vented by the at least one capillary loop is received by the liquid jet ejector pump. The vaporized cooling fluid is combined the cooling fluid within the liquid jet ejector pump circulates the cooling fluid through the secondary loop.

According to another embodiment, a cooling system is provided. The cooling system includes a heat-generating device and a cooler loop assembly. The cooler loop assembly includes a manifold thermally coupled to the heat-generating device, a pump loop, and a secondary loop. The pump loop has a pump and is fluidly coupled to the manifold. The pump is configured to move a cooling fluid through the manifold to cool the heat-generating device. A vaporized cooling fluid is generated by the cooling of the heat-generating device and is vented by the manifold. The secondary loop has a liquid jet ejector pump. The secondary loop is fluidly coupled to the manifold such that the vaporized cooling fluid vented by the manifold is received by the liquid jet ejector pump. The vaporized cooling fluid is combined with the cooling fluid within the liquid jet ejector pump to circulate the cooling fluid through the secondary loop.

According to a further embodiment, a method for cooling a heat-generating device is provided. The method includes pumping a cooling fluid through a pump loop and a capillary loop to cool the heat-generating device, the pump loop having a pump and a heat exchanger, the pump loop fluidly coupled to the capillary loop, the capillary loop having a manifold in which the heat- generating device is thermally coupled thereto, the pump is configured to move the cooling fluid through the manifold to cool the heat-generating device, venting a vaporized cooling fluid from the capillary loop to a secondary loop having a liquid jet ejector pump, and driving the cooling fluid through the secondary loop via the liquid jet ejector pump based on an amount of the vaporized cooling fluid vented through the capillary loop provided to the liquid jet ejector pump to circulate the cooling fluid in the secondary loop, the secondary loop is parallel to the pump loop.

Additional features and advantages of the technology described in this disclosure will be set forth in the detailed description which follows, and in part will be readily apparent to those skilled in the art from the description or recognized by practicing the technology as described in this disclosure, including the detailed description which follows, the claims, as well as the appended drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a first aspect of an example cooling system according to one or more embodiments shown and described herein;

FIG. 2A schematically depicts a perspective view of a manifold assembly of the example cooling system of FIG. 1 according to one or more embodiments shown and described herein;

FIG. 2B schematically depicts a cross-sectional view of the manifold assembly taken from line 2B-2B of FIG. 2A according to one or more embodiments shown and described herein;

FIG. 3 schematically depicts a side view of a liquid jet ejector pump of the example cooling system of FIG. 1 according to one or more embodiments shown and described herein;

FIG. 4 schematically depicts a second aspect of an example cooling system according to one or more embodiments shown and described herein; and

FIG. 5 schematically depicts a flow diagram that graphically depicts an illustrative method of passively driving a cooling fluid through a secondary loop of the example cooling system of FIG. 1 according to one or more embodiments shown and described herein.

### DETAILED DESCRIPTION

Embodiments of the present disclosure are directed to example cooling systems that include a targeted inclusion of a plurality of capillary loop jets within a capillary cooler loop. The example cooling systems further include a pump loop to cool components such as components within a vehicle that require aggressive cooling, for example, a motor. However, as electrification in vehicles increases, the pump power needed for cooling is also increased, which lowers the efficiency of the cooling system. As such, the embodiments of the present disclosure reduce the pump load of the pump with passive cooling mechanisms. That is, capillary coolers are used to draw fluid in parallel loops to cool target subsystems, which may be low power systems with low heat flux or low cooling requirements, such as, without limitation, battery(ies), sensors, and the like. This capillary action thus removes the pumping power required to cool these secondary systems.

In conventional cooling systems, generated vapor is sent directly to a reservoir where the vapor will be condensed. In the embodiments described herein, the vapor byproduct is utilized to drive or circulate the cooling fluid within auxiliary or secondary loops without the need of an active pump to move the cooling fluid. That is, the vapor generator from the capillary loop will not return directly to the reservoir, but will be directed to a liquid jet ejector pump. In some embodiments, the liquid jet ejector pump is a steam injector, which is configured to drive or circulate the cooling fluid through the auxiliary or secondary loops. The amount of vapor directed to the liquid jet ejector pump can be modulated using a vapor bypass valve on a bypass passage. Upon movement of the vapor bypass valve from a normally closed position to an open position, some vapor will be directed back to the reservoir. In some embodiments, the reservoir includes a separating plate to at least partially isolate the pump loop from the auxiliary or secondary loops. The separating plate prevents or inhibits the pump of the pump loop from driving cooling fluid through the auxiliary or secondary loop. Further, a height (e.g., a vertical length in the +/−Z direction) of the separator plate may be tuned to allow overflow once the cooling fluid builds up in the auxiliary or secondary loop. This arrangements prevents the pump loop from drying out. Further, the separator plate may be configured to permit a predetermined amount of cooling fluid to return to the pump loop given a fluid volume of the cooling loop in the auxiliary or secondary loop is constantly increasing with the inclusion of the vapor.

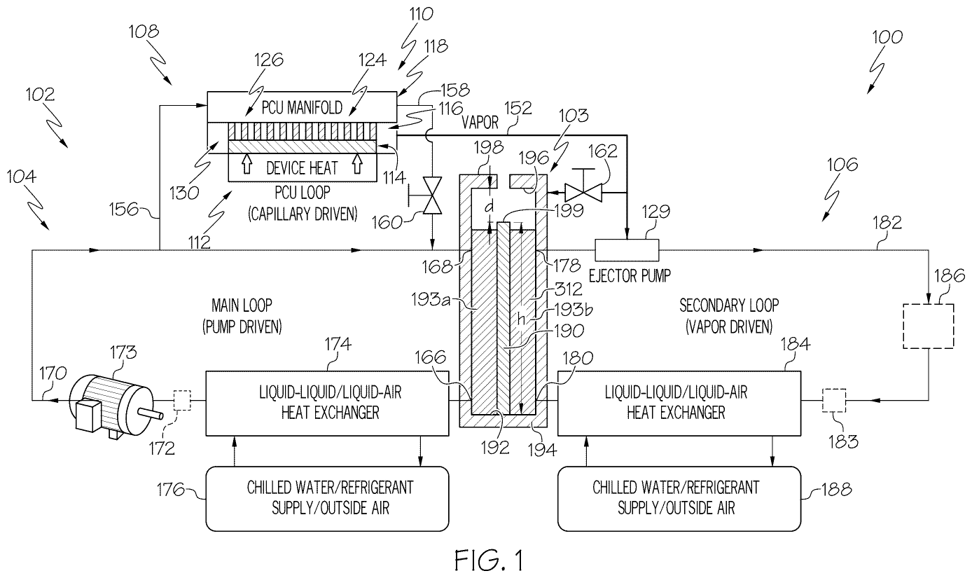

Referring initially to FIG. 1, an example cooling system 100 is schematically depicted. The cooling system 100 may include a cooler loop assembly 102. The cooler loop assembly 102 may include a reservoir 103, a pump loop 104, a secondary loop 106, and/or at least one capillary loop 108. The at least one capillary loop 108 may include an example manifold assembly 110 and a heat-generating device 112. As such, the heat-generating device 112 may be thermally coupled to the at least one capillary loop 108.

That is, in some embodiments, the heat-generating device 112 may be bonded to portions of the example manifold assembly 110 via a thermal interface layer to be in thermal communication with the at least one capillary loop 108. The thermal interface layer may include a thermally conductive bond and may include a DBC (direct bonded copper) substrate, solder, or some other high temperature substrate, bonding material, or method. In other embodiments, the thermal interface layer may be a thermal grease positioned between a surface of the heat-generating device 112 and a surface of the example manifold assembly 110.

The heat-generating device 112 may be a central processing unit (CPU) or a graphics-processing unit (GPU) that uses integrated circuits and are commonly found and associated with data centers. Further, the heat-generating device 112 may be a power device that may include one or more semiconductor devices such as, but not limited to, an insulated gate bipolar transistor (IGBT), a reverse conducting IGBT (RC-IGBT), a metal-oxide-semiconductor field-effect transistor (MOSFET), a power MOSFET, a diode, a transistor, and/or combinations thereof. In some embodiments, the heat-generating device 112 may include a wide-bandgap semiconductor, and may be formed from any suitable material such as, but not limited to, silicon carbide (SiC), silicon dioxide (SiO2), aluminum nitride (AlN), gallium nitride (GaN), and boron nitride (BN), and the like. In some embodiments, the heat-generating device 112 may include ultra-wide-bandgap devices formed from suitable materials such as AlGaN/AlN, Ga2O3, and diamond. In some embodiments, the heat-generating device 112 may operate within a power module having a high current and/or a high power and under high temperatures (for example, in excess of 100° C., 150° C., 175° C., 200° C., 225° C., or 250° C.) and dissipate a large amount of power in the form of heat that must be removed for the continued operation of the heat-generating device 112.

Accordingly, the heat-generating device 112 may be suitable in vehicle power electronics, in data center applications with integrated circuits, and the like. The heat generated by the heat-generating device 112 may be conducted away via the example manifold assembly 110 to cool the heat-generating device 112, as discussed in greater detail herein. Further, the heat-generating device 112 may be any shape or size.

The example manifold assembly 110 may include a cold plate assembly 114, which includes a cold plate 115, a fluid wicking structure 116, and a manifold case 118. In some embodiments, a base wick or other porous structure may be positioned between the cold plate 115 and the fluid wicking structure 116. The manifold case 118 may act as a cover to enclose portions of the cold plate 115 and the fluid wicking structure 116, as discussed in greater detail herein.

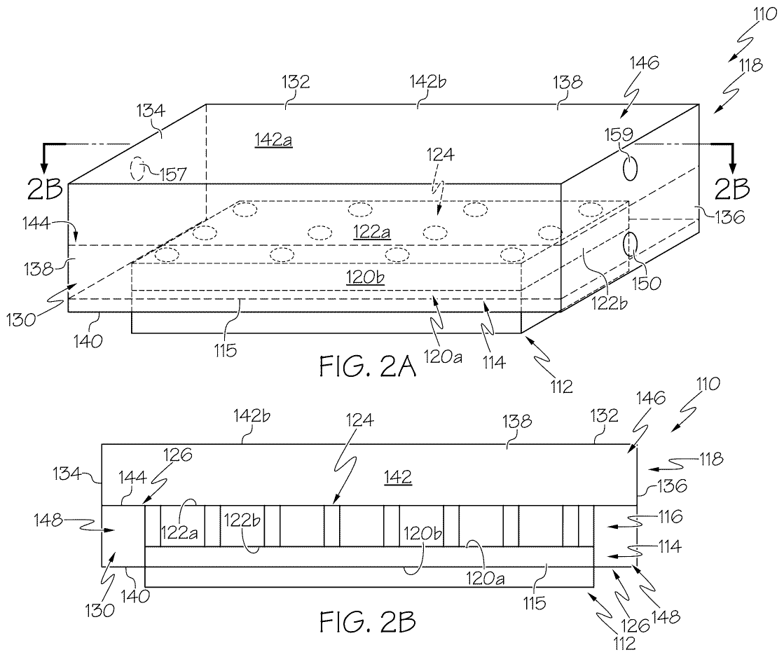

As best illustrated in FIG. 2, the cold plate 115 may be a substrate or planar sheet that has a fluid wicking receiving surface 120a and an opposite device receiving surface 120b. The fluid wicking receiving surface 120a may be in contact with, or abut, the fluid wicking structure 116. That is, the fluid wicking receiving surface 120a may be planar and provide a mounting or coupling surface for the fluid wicking structure 116 to rest on, abut, bond onto, and the like, as discussed in greater detail herein.

It should be appreciated that the cold plate assembly 114 may be formed by etching a silicon wafer or by micromachining a Cu substrate. As such, in some embodiments, portions of the cold plate assembly 114 may be formed from a silicon material. In other embodiments, portions of the cold plate assembly 114 may formed from be Cu, AlSiC, or other materials. Further, a thickness of the cold plate assembly 114 and components thereof (i.e., cold plate 115, fluid wicking structure 116, and/or manifold 118) may depend on the intended use of example manifold assembly 110. That is, the thickness may vary depending on whether the heat-generating device 112 is an integrated circuit CPU/GPU or a power electronic semiconductor. As such, the illustrated embodiments and present disclosure are non-limiting as the thickness of the cold plate assembly 114 varies.

In some embodiments, portions of the cold plate assembly 114 may be dimensionally sized to match, or be equal to the size of the heat-generating device 112 coupled to the device receiving surface 120b. In the depicted embodiments, the cold plate 115 is generally depicted in a rectangular shape. This is non-limiting and the cold plate 115 may be any shape, including, without limitation, square, hexagonal, octagonal, circular, triangular, and/or the like. As such, the cold plate 115 may be any shape, size, and/or dimension.

Still referring to FIG. 2, the fluid wicking structure 116 may include an upper surface 122a and an opposite lower surface 122b. A plurality of microchannels 124 are formed to extend through the upper surface 122a and the lower surface 122b. Each of the plurality of microchannels 124 may be shaped and sized to allow at least a portion of a cooling fluid of the cooler loop assembly 102 to be passed therethrough. The plurality of microchannels 124 may be of any suitable size. In embodiments, each of the plurality of microchannels 124 may have a length of 50 μm, 100 μm, 300 μm, 500 μm, 1000 μm, 5000 μm, or any other suitable size.

Further, it should be understood that in embodiments, any suitable number of microchannels 124 may be used. As a non-limiting example, the fluid wicking structure 116 may include two microchannels 124, three microchannels 124, five microchannels 124, ten microchannels 124, fifty microchannels 124, or any other suitable number of microchannels 124.

While each of the plurality of microchannels 124 are shown as being of equal size, it should be understood that, in embodiments, the plurality of microchannels 124 may be of various sizes, such that some of the plurality of microchannels 124 may be larger than other of the plurality of microchannels 124.

The plurality of microchannels 124 are configured to wick the cooling fluid from a liquid supply of the pump loop 104 and/or the at least one capillary loop 108 through one or more of the plurality of microchannels 124. This may provide for even and consistent cooling fluid coverage across the cold plate 114.

The fluid wicking structure 116 may further include a plurality of vapor gaps 126 formed between each of the plurality of microchannels 124. The plurality of vapor gaps 126 may be of any suitable size. In embodiments, each of the plurality of vapor gaps 126 may have a length of 50 μm, 100 μm, 300 μm, 500 μm, 1000 μm, 5000 μm, or any other suitable size.

It should be understood that in embodiments, any suitable number of vapor gaps 126 may be used. As a non-limiting example, the fluid wicking structure 116 may include two vapor gaps 126, three vapor gaps 126, five vapor gaps 126, ten vapor gaps 126, fifty vapor gaps 126, or any other suitable number of vapor gaps 126.

While each of the plurality of vapor gaps 126 are shown as being of equal size, it should be understood that, in embodiments, the plurality of vapor gaps 126 may be of various sizes, such that some of the plurality of vapor gaps 126 may be larger than other of the plurality of vapor gaps 126.

Each of the plurality of vapor gaps 126 are shaped and sized to allow the vaporized cooling fluid to be passed therethrough. This may allow for vaporized cooling fluid to exit the example manifold assembly 110 to a liquid jet ejector pump 129, as discussed in greater detail herein. The vaporized cooling fluid may then utilized to power or drive the liquid jet ejector pump 129 of the secondary loop 106 to passively drive the cooling fluid through the secondary loop 106, as discussed in greater detail herein.

The manifold case 118 is configured to cover, or enclose, the fluid wicking structure 116 and at least portions of the cold plate 114, as discussed in greater detail herein. In particular, the manifold case 118 further includes a receiving portion 130 that is preformed or predefined to be sized and shaped to dimensionally to receive the fluid wicking structure 116 and the cold plate 114 when the manifold case 118 is positioned to abut the heat-generating device 112.

The receiving portion 130 may include an upper wall 132, an inlet wall 134, an opposite outlet wall 136, a pair of sidewalls 138 and an end wall 140 positioned to extend between the inlet wall 134, the outlet wall 136, and the pair of sidewalls 138 and may be parallel with the upper wall 132. Each of the upper wall 132, the inlet wall 134, the outlet wall 136, the pair of sidewalls 138, and the end wall 140 have an interior surface 142a and an opposite exterior surface 142b. The receiving portion 130 may be dimensionally shaped to receive the fluid wicking structure 116 and the cold plate 114 when the manifold case 118 is positioned to abut the heat-generating device 112.

In embodiments, a partition wall 144 extends from the interior surface 142a circumferentially within the receiving portion 130 to form or define a fluid pooling portion 146. The fluid pooling portion 146 is positioned above the partition wall 144 in the vertical direction (i.e., in the +/−Z direction) while a vapor space portion 148 is positioned below the partition wall 144 in the vertical direction (i.e., in the +/−Z direction) In the depicted embodiments, at least one vapor bore 150 extends from the outlet wall 136 through the interior and exterior surfaces 142a, 142b, below the partition wall 144 (i.e., in the +/−Z direction) and from the vapor space portion 148 to be fluidly coupled to the vapor space portion 148 and to a vapor passage 152, as discussed in greater detail herein.

The manifold case 118 may be made of non-conductive material such as a plastic, a ceramic, or a composite material and may be formed via traditional methods such as injection molding, and/or may be formed via additively manufacturing methods. As used herein, the terms “additively manufactured” or “additive manufacturing techniques or processes” refer generally to manufacturing processes wherein successive layers of material(s) are provided on each other to “build-up,” layer-by-layer, a three-dimensional component. The successive layers generally fuse together to form a monolithic component which may have a variety of integral sub-components. Although additive manufacturing technology is described herein as enabling fabrication of complex objects by building objects point-by-point, layer-by-layer, typically in a vertical direction, other methods of fabrication are possible and within the scope of the present subject matter. For example, although the discussion herein refers to the addition of material to form successive layers, one skilled in the art will appreciate that the methods and structures disclosed herein may be practiced with any additive manufacturing technique or manufacturing technology. For example, embodiments of the present invention may use layer-additive processes, layer-subtractive processes, or hybrid processes.

Suitable additive manufacturing techniques in accordance with the present disclosure may include, for example and without limitation, Fused Deposition Modeling (FDM), Selective Laser Sintering (SLS), 3D printing such as by inkjets and laserjets, Sterolithography (SLA), Direct Selective Laser Sintering (DSLS), Electron Beam Sintering (EBS), Electron Beam Melting (EBM), Laser Engineered Net Shaping (LENS), Laser Net Shape Manufacturing (LNSM), Direct Metal Deposition (DMD), Digital Light Processing (DLP), Direct Selective Laser Melting (DSLM), Selective Laser Melting (SLM), Direct Metal Laser Melting (DMLM), and other known processes.

The additive manufacturing processes described herein may be used for forming components using any suitable material. For example, the material may be plastic, metal, concrete, ceramic, polymer, epoxy, photopolymer resin, or any other suitable material that may be in solid, liquid, powder, sheet material, wire, or any other suitable form. More specifically, according to exemplary embodiments of the present subject matter, the additively manufactured components described herein may be formed in part, in whole, or in some combination of materials including but not limited to pure metals, nickel alloys, chrome alloys, titanium, titanium alloys, magnesium, magnesium alloys, aluminum, aluminum alloys, and nickel or cobalt base superalloys (e.g., those available under the name Inconel® available from Special Metals Corporation). These materials are examples of materials suitable for use in the additive manufacturing processes described herein, and may be generally referred to as “additive materials.”

In addition, one skilled in the art will appreciate that a variety of materials and methods for bonding those materials may be used and are contemplated as within the scope of the present disclosure. As used herein, references to “fusing” may refer to any suitable process for creating a bonded layer of any of the above materials. For example, if an object is made from polymer, fusing may refer to creating a thermoset bond between polymer materials. If the object is epoxy, the bond may be formed by a crosslinking process. If the material is ceramic, the bond may be formed by a sintering process. If the material is powdered metal, the bond may be formed by a melting or sintering process. One skilled in the art will appreciate that other methods of fusing materials to make a component by additive manufacturing are possible, and the presently disclosed subject matter may be practiced with those methods.

In addition, the additive manufacturing process disclosed herein allows a single component to be formed from multiple materials. Thus, the components described herein may be formed from any suitable mixtures of the above materials. For example, a component may include multiple layers, segments, or parts that are formed using different materials, processes, and/or on different additive manufacturing machines. In this manner, components may be constructed which have different materials and material properties for meeting the demands of any particular application. In addition, although the components described herein are constructed entirely by additive manufacturing processes, it should be appreciated that in alternate embodiments, all or a portion of these components may be formed via casting, machining, and/or any other suitable manufacturing process. Indeed, any suitable combination of materials and manufacturing methods may be used to form these components.

An exemplary additive manufacturing process will now be described. Additive manufacturing processes fabricate components using three-dimensional (3D) information, for example a three-dimensional computer model, of the component. Accordingly, a three-dimensional design model of the component may be defined prior to manufacturing. In this regard, a model or prototype of the component may be scanned to determine the three-dimensional information of the component. As another example, a model of the component may be constructed using a suitable computer aided design (CAD) program to define the three-dimensional design model of the component.

The design model may include 3D numeric coordinates of the entire configuration of the component including both external and internal surfaces of the component. For example, the design model may define the body, the surface, and/or internal passageways such as openings, support structures, and the like. In one exemplary embodiment, the three-dimensional design model is converted into a plurality of slices or segments, e.g., along a central (e.g., vertical) axis of the component or any other suitable axis. Each slice may define a thin cross section of the component for a predetermined height of the slice. The plurality of successive cross-sectional slices together form the 3D component. The component is then “built-up” slice-by-slice, or layer-by-layer, until finished.

In this manner, the components described herein may be fabricated using the additive process, or more specifically each layer is successively formed, e.g., by fusing or polymerizing a plastic using laser energy or heat or by sintering or melting metal powder. For example, a particular type of additive manufacturing process may use an energy beam, for example, an electron beam or electromagnetic radiation such as a laser beam, to sinter or melt a powder material. Any suitable laser and laser parameters may be used, including considerations with respect to power, laser beam spot size, and scanning velocity. The build material may be formed by any suitable powder or material selected for enhanced strength, durability, and useful life, particularly at high temperatures.

As such, it should be understood that any or all of the components of the example manifold assembly 110 may be formed using additively manufacturing process to include, without limitation, the cold plate 115, the fluid wicking structure 116, and the manifold case 118.

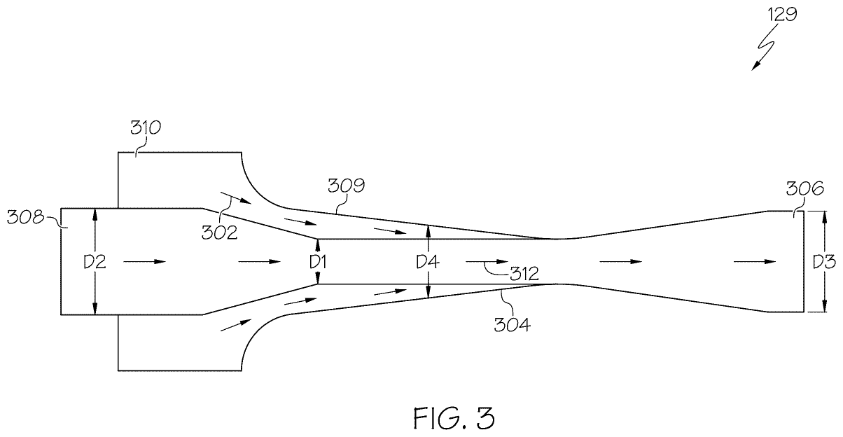

The at least one capillary loop 108 further includes the vapor passage 152 that is fluidly coupled to the at least one vapor bore 150 such that the vapor passage 152 may be external to the manifold case 118. That is, the at least one vapor bore 150 may provide a fluid channel or void from the vapor space portion 148 of the receiving portion 130 and through the outlet wall 136 of the manifold case 118 such that a vapor (depicted by the arrow 302 in FIG. 3) generated or created in the vapor space portion 148 may exit the manifold case 118 via the at least one vapor bore 150 to enter the vapor passage 152, as discussed in greater detail herein. As such, the at least one vapor bore 150 is fluidly coupled to the vapor passage 152, which is fluidly coupled to the liquid jet ejector pump 129. Therefore, a fluid path exists from the vapor space portion 148 of the receiving portion 130, through the outlet wall 136 of the manifold case 118 via the at least one vapor bore 150, through the vapor passage 152 and into the liquid jet ejector pump 129, as discussed in greater detail herein. It should be understood that the at least one vapor bore 150 may be any shape such as, without limitation, cylindrical, hexagonal, octagonal, square, rectangular, any irregular or regular shape, and the like.

A vapor bypass valve 162 may be positioned on the vapor passage 152 downstream of the example manifold assembly 110 and upstream of the secondary loop 106. The vapor bypass valve 162 is switchable between a normally closed position, an open position, and a plurality of positions therebetween. In any position other than the closed position (e.g., the open position of any degree of open position), the vapor bypass valve 162 allows for the vapor from the example manifold assembly 110 to flow from the at least one capillary loop 108 into the reservoir 103. In the closed position, the vapor bypass valve 162 inhibits any of the vapor flowing from the example manifold assembly 110 through the vapor bypass valve 162 and into the reservoir 103. Instead, in the closed position, any of the vapor expelled from the example manifold assembly 110 is directed to the liquid jet ejector pump 129. As such, the amount of the vapor that may be directed to the liquid jet ejector pump 129 may be modulated using vapor bypass valve 162.

The at least one capillary loop 108 further includes a fluid inlet passage 156 and a fluid outlet passage 158. Both of the fluid inlet passage 156 and the fluid outlet passage 158 are fluidly coupled to the pump loop 104 and to the example manifold assembly 110 via at least one fluid inlet bore 157 and at least one fluid outlet bore 159, respectively. That is, the at least one fluid inlet bore 157 may fluidly couple the fluid inlet passage 156 and the example manifold assembly 110 and the at least one fluid outlet bore 159 may be fluidly couple the example manifold assembly 110 and the fluid outlet passage 158. As such, each of the at least one fluid inlet bore 157 and the at least one fluid outlet bore 159 may provide a fluid channel or void through the manifold case 118 and into the fluid pooling portion 146 of the example manifold assembly 110. As such, the cooling fluid may enter the manifold case 118 and into the fluid pooling portion 146 of the example manifold assembly 110 via the fluid inlet passage 156 through the at least one fluid inlet bore 157 and portions of the cooling fluid that is not wicked to the cold plate 114 may exit the fluid pooling portion 146 of the example manifold assembly 110 via the at least one fluid outlet bore 159 to the fluid outlet passage 158. It should be understood that each of the at least one fluid inlet bore 157 and the at least one fluid outlet bore 159 may be any shape, the same shape or different shapes and may be, without limitation, cylindrical, hexagonal, octagonal, square, rectangular, any irregular or regular shape, and the like. Further, there may be a same amount of bores, different amount of bore, and the like.

It should be understood that the fluid inlet passage 156 is a feeder passage from the pump loop 104 to the example manifold assembly 110 and the fluid outlet passage 158 transfers any unused and/or heated cooling fluid from the example manifold assembly 110 back to the pump loop 104. In some embodiments, a fluid outlet valve 160 is positioned on the fluid outlet passage 158 downstream of the example manifold assembly 110 and upstream of the pump loop 104. The fluid outlet valve 160 is switchable between a normally open position, a closed position, and a plurality of positions therebetween. In any position other than the closed position (e.g., the open position of any degree of open position), the fluid outlet valve 160 allows heated and/or excess cooling fluid from the example manifold assembly 110 to flow into the return of the pump loop 104. In the closed position, the fluid outlet valve 160 inhibits any cooling fluid flowing from the example manifold assembly 110 through the fluid outlet valve 160 and into the pump loop 104.

It should also be understood that the at least one capillary loop 108 is configured to draw in cooling fluid in parallel loops (e.g. parallel with the pump loop 104) to cool target subsystems such as the heat-generating device 112. The capillary action thus removes the pumping power required to cool the heat-generating device 112. Further, it should be understood that while only at least one capillary loop 108 is depicted in FIG. 1, there may be a plurality of capillary loops arranged in parallel with the pump loop 104. As such, there may be more capillary loops for additional heat-generating devices.

Still referring to FIG. 1, the pump loop 104 is fluidly coupled to the reservoir 103 at a pump loop outlet passage 166 and a pump loop inlet passage 168. A pump loop passage 170 may be fluidly coupled to both the pump loop outlet passage 166 and the pump loop inlet passage 168. Further, the pump loop passage 170 may be fluidly coupled to the fluid inlet passage 156 to provide or feed the cooling fluid to the fluid inlet passage 156 and may be fluidly coupled to the fluid outlet passage 158 to receive the cooling fluid from the at least one capillary loop 108.

The pump loop 104 may include a pump 172 and a heat exchanger 174. In some embodiments, the pump 172 may be positioned within the reservoir 103. In other embodiments, the pump may be positioned downstream of the reservoir 103. The pump 172 may be configured to assist in moving the cooling fluid from the reservoir 103 and/or the heat exchanger 174, through the pump loop 104 and into the at least one capillary loop 108. As a non-limiting example, the pump 172 may be a positive-displacement pump, centrifugal pump, axial-flow pump, or any other suitable type of pump. It should be appreciated that while the pump 172 is shown in FIG. 1 as a single pump, any number of pumps can be used. The pump 172 is configured to move the cooling fluid within the pump loop passage 170 at a predetermined flow rate that may be based on the components that are desired to be cooled. The cooling fluid may be, without limitation, water, glycol-water solutions, dielectric fluid, or any other fluid suitable for cooling electronic devices.

The heat exchanger 174 may be a liquid-liquid heat exchanger, a liquid-air heat exchanger, and/or the like. The heat exchanger 174 may be fluidly coupled to an external supply device 176. For example, and without limitation, the external supply device 176 may be a chilled water or refrigerant supply, an outside or external air supply, and the like.

The pump loop 104 may be configured to cool various components 173 that require aggressive cooling, such as those components that expel a heat above a predetermined threshold amount without constant or near constant cooling fluid driven by or near the component to remove expelled heat. Example components that may require aggressive cooling may include, without limitation, a motor, an engine, and the like. That is, some components may be passively cooled and do not require aggressive cooling such as those with a low heat flux or low power, for example, and without limitation, battery, sensor, and some heat-generating devices as discussed above. Other devices require aggressive cooling to remove undesired heat.

Still referring to FIG. 1, the secondary loop 106 is fluidly coupled to the reservoir 103 at a secondary loop outlet passage 178 and a secondary loop inlet passage 180. A secondary loop passage 182 is fluidly coupled to both the secondary loop outlet passage 178, the secondary loop inlet passage 180, and the liquid jet ejector pump 129. The secondary loop 106 may be passively driven by the liquid jet ejector pump 129. As such, there is not a pump in the secondary loop 106 and instead the liquid jet ejector pump 129 passively drives the cooling fluid through the secondary loop 106 by utilizing the expelled vapor from the at least one capillary loop 108, as discussed in greater detail herein. The secondary loop 106 may further include a heat exchanger 184. The liquid jet ejector pump 129 may be positioned downstream of the reservoir 103 and upstream of the heat exchanger 184 and upstream from a plurality of secondary components 186 that require heat removal. The liquid jet ejector pump 129 may be configured to assist in moving the cooling fluid from the reservoir 103 through the secondary loop passage 182 to cool the plurality of secondary components 186. As a non-limiting example, the plurality of secondary components 186 may include batteries, power modules, inventers, sensors, and the like, which do not require the aggressive cooling needed by the components of the pump loop 104. As such, the secondary loop 106 is configured to cool lower power consumption devices, which may be placed throughout a vehicle. It should be understood that, in some embodiments, additional heat exchangers may be utilized to reduce the temperature of the cooling fluid cool heat generating components. In other embodiments, the heat exchanger 184 may or may not be needed. It should also be appreciated that while one of the liquid jet ejector pump 129 is shown in FIG. 1, any number of liquid jet ejector pumps can be used.

In some embodiments, a plurality of micro-fin structures 183 may be positioned within the secondary loop passage 182. Each of the plurality of micro-fin structures 183 may be configured to reduce a temperature of the cooling fluid within the secondary loop passage 182.

The heat exchanger 184 may be a liquid-liquid heat exchanger, a liquid-air heat exchanger, and/or the like. The heat exchanger 184 may be fluidly coupled to an external supply device 188. For example, and without limitation, the external supply device 188 may be a chilled water or refrigerant supply, an outside or external air supply, and the like.

Still referring to FIG. 1, the reservoir 103 includes a member 190 extending from an inner surface 192 of an end wall 194. The member 190 has a thickness to generally separate or isolate the cooling fluid received from the pump loop 104 and the secondary loop 106. As such, the member 190 may be a planar plate. The member 190 generally inhibits the pump 172 from driving the cooling fluid through the secondary loop 106. In some embodiments, the member 190 extends a height “H” from the inner surface 192 in a vertical direction (i.e., in the +/−Z direction), which may define a first compartment 193a and a second compartment 193b independent from the first compartment 193a (e.g., the member 190 may be a separating member). The height H of the member 190 may be varied to tune the reservoir 103 to permit or allow an overflow of the cooling fluid from the secondary loop 106 to drain into the other side of the member 190 for the pump loop 104 (e.g., from the second compartment 193b to the first compartment 193a.) As such, the member 190 does not extend to an inner surface 196 of an upper end wall 198. That is, there is a gap between a terminating surface 199 of the member 190 and the inner surface 196 of the upper end wall 198 illustrated by the “d” in FIG. 1. As such, the member 190 of the reservoir 103 is configured to extend in a predetermined height direction to allow for fluid communication (e.g., the cooling fluid) between the second compartment and the first compartment.

Such tuning prevents the pump loop 104 from drying out due to the increased need for cooling fluid due to required aggressively cooled components. Further, the tuning of the member 190 permits for some of the cooling fluid to return to the pump loop 104 given that the fluid volume in the secondary loop 106 may be constantly, or intermittently increasing with inclusion of the vapor. As such, the tuning permits for the balance of the cooling fluid between the pump loop 104 and the secondary loop 106.

It should be understood that the at least one capillary loop 108 of the example cooling system 100 releases or directs excess subcooled cooling fluid back into the pump loop 104 and the vapor generated from the manifold assembly 110 of the at least one capillary loop 108 is directed to the liquid jet ejector pump 129 to passively drive the cooling fluid through the secondary loop 106.

Now referring to FIG. 3, the liquid jet ejector pump 129 includes a cooling fluid jet passage 304, a diffuser portion 306, a cooling fluid inlet 308, a mixing nozzle 309, and a vapor inlet 310. The cooling fluid inlet 308 may be fluidly coupled to the reservoir 103 via the secondary loop outlet passage 178. The vapor inlet 310 may be fluidly coupled to the vapor passage 152 and to the mixing nozzle 309. The diffuser portion 306 may be fluidly coupled to the secondary loop passage 182. The cooling fluid jet passage 304 may have a smaller diameter D1 than a diameter D2 of the cooling fluid inlet 308 and a diameter D3 of the diffuser portion 306. Further, the diameter D1 of the cooling fluid jet passage 304 may less than a diameter D4 of the mixing nozzle 309, which may be tapering or sloping in the direction of the diffuser portion 306 to have a constant change in size. In some embodiments, the diameter D2 of the cooling fluid inlet 308 may be larger than the diameter D3 of the diffuser portion 306. In other embodiments, the diameter D2 of the cooling fluid inlet 308 may be equal to the diameter D3 of the diffuser portion 306. In other embodiments, the diameter D2 of the cooling fluid inlet 308 may be less than the diameter D3 of the diffuser portion 306. Further, portions of the cooling fluid inlet 308 may taper in a direction towards the diffuser portion 306 such that portions of the cooling fluid jet passage 304 have varying diameters. The vapor 302 is configured to mix with the cooling fluid 312 in the mixing nozzle 309 to form the water jet.

That is, in operation, the vapor 302 will exit the example manifold assembly 110 and is fed to the liquid jet ejector pump 129. Further, the cooling fluid 312 is fed from the reservoir 103 to the liquid jet ejector pump 129. The subcooled cooling fluid is fed through the mixing nozzle 309 where the vapor 302 is mixed into the cooling fluid 312, which transfers momentum from the vapor 302 to the cooling fluid 312, thus accelerating the cooling fluid 312. As the vapor 302 condenses to liquid in the mixing nozzle 309, the high-speed sub-cool liquid kinetic energy is converted to a pressure at the diffuser portion 306. This rise in pressure causes the cooling fluid 312 to flow within the secondary loop passage 182 without any external energy source (e.g., without a pump or other mechanical device).

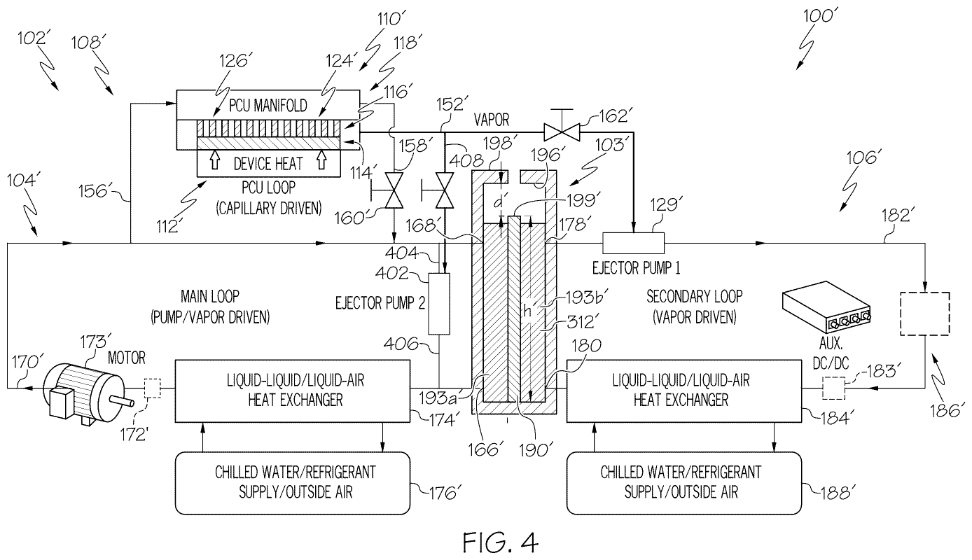

Now referring to FIG. 4, a second aspect of the example cooling system 100′ schematically depicted. It is understood that the example cooling system 100′ is similar to the example cooling system 100 with the exceptions of the features described herein. As such, like features will use the same reference numerals with a suffix “′” for the reference numbers. As such, for brevity reasons, these features will not be described again.

The example cooling system 100′ includes a second liquid jet ejector pump 402 that is similar to the liquid jet ejector pump 129, with the exception that the second liquid jet ejector pump 402 is fluidly coupled to the pump loop 104. That is, vapor expelled from the example manifold assembly 110 may be directed to either or both of the liquid jet ejector pump 129 and/or the second liquid jet ejector pump 402. As such, the second liquid jet ejector pump 402 is fluidly coupled to the pump loop passage 170′ such that an inlet passage 404 of the second liquid jet ejector pump 402 is positioned upstream of the reservoir 103′ and an outlet passage 406 of the second liquid jet ejector pump 402 is positioned downstream of the reservoir 103′. In some embodiments, the outlet passage 406 may be position downstream of the heat exchanger 174′.

The vapor passage 152′ includes a second vapor valve 408 positioned to be upstream of the second liquid jet ejector pump 402. In some embodiments, the second vapor valve 408 may also be positioned upstream of the vapor valve 162′. Both of the second vapor valve 408 and the vapor valve 162′ are fluidly coupled to the vapor passage 152′. Further, the second vapor valve 408 is fluidly coupled to the second liquid jet ejector pump 402 while the vapor valve 162′ is fluidly coupled to the liquid jet ejector pump 129′. The combination of the vapor valve 162′ and the second vapor valve 408 may be configured as vapor throttling valves for periodically adjusting an amount of the cooling fluid between the pump loop 104′ and the secondary loop 106′ to balance the cooling fluid or for accommodating time-varying loads. Such an arrangement assists in propelling the cooling fluid through the pump loop 104 and reducing the total pumping load required. As such, the pump loop 104′ may be pump driven and vapor driven, either simultaneously (e.g., both the pump 172′ and the second liquid jet ejector pump 402 activated), or independently by the pump 172′ or the second liquid jet ejector pump 402. In other embodiments, the combination of the vapor valve 162′ and the second vapor valve 408 may close the secondary loop 106′ when the components 186′ are not in use.

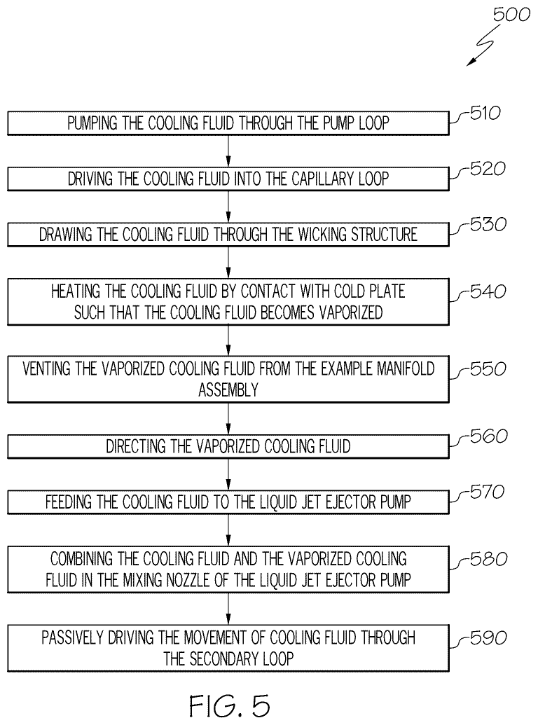

Referring now to FIG. 5, a flow diagram that graphically depicts an illustrative method 500 of passively driving the cooling fluid through the secondary loop is provided. Although the steps associated with the blocks of FIG. 5 will be described as being separate tasks, in other embodiments, the blocks may be combined or omitted. Further, while the steps associated with the blocks of FIG. 5 will described as being performed in a particular order, in other embodiments, the steps may be performed in a different order.

At block 510, the cooling fluid is pumped through the pump loop. In some embodiments, the cooling fluid is pumped through the pump loop via the pump. In other embodiments, the liquid jet ejector pump may be utilized either alone or in combination with the pump. At block 520, the cooling fluid is driven into the example manifold assembly via the capillary loop. At block 530, at least a portion of the cooling fluid is drawn through fluid wicking structure. That is, the cooling fluid may be drawn through the fluid wicking structure towards the heat-generating device.

At block 540, the cooling fluid makes contact with the cold plate to heat the cooling fluid with heat expelled from the heat-generating device such that the cooling fluid becomes vaporized. That is, the heat from the heat-generating device may be transferred to the cooling fluid such that the cooling fluid becomes vaporized. At block 550, the vaporized cooling fluid is vented from the example manifold assembly. The vaporized cooling fluid is vented into the vapor passage.

At block 560, the vaporized cooling fluid is directed to the liquid jet ejector pump and feeding the cooling fluid from the reservoir to the liquid jet ejector pump, at block 570. At block 580, the vaporized cooling fluid is combined with the cooling fluid in the mixing nozzle of the liquid jet ejector pump to accelerate the cooling fluid. In response, at block 590, the cooling fluid is passively driven through the secondary loop passage without any external energy source (e.g., without a pump or other mechanical device).

Embodiments of the present disclosure provide example cooling systems that include a targeted inclusion of a plurality of capillary loop jets within a capillary cooler loop, a pump loop to cool components such as components within a vehicle that require aggressive cooling, and a secondary loop that is passively driven to reduce a pump load of a pump. In the embodiments described herein, a vapor byproduct from a pump loop/capillary loop is utilized to drive auxiliary or secondary loops without the need of an active pump to move the cooling fluid. That is, the vapor generator from the capillary loop will not return to a reservoir, but will be directed to a liquid jet ejector pump. The amount of vapor directed to the liquid jet ejector pump can be modulated using a vapor bypass valve on a bypass passage.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A cooling system comprising:
a heat-generating device; and
a cooler loop assembly comprising:
at least one capillary loop thermally coupled to the heat-generating device;
a pump loop having a pump, the pump loop fluidly coupled to the at least one capillary loop, the pump is configured to move a cooling fluid through the pump loop and the at least one capillary loop to cool the heat-generating device, a vaporized cooling fluid generated by the cooling of the heat-generating device vented by the at least one capillary loop; and
a secondary loop having a liquid jet ejector pump, the secondary loop fluidly coupled to the at least one capillary loop such that the vaporized cooling fluid vented by the at least one capillary loop is received by the liquid jet ejector pump,
wherein the vaporized cooling fluid is combined with the cooling fluid within the liquid jet ejector pump to circulate the cooling fluid through the secondary loop.

2. The cooling system of claim 1, wherein the secondary loop is passively driven by the vaporized cooling fluid generated from the heat-generating device.

3. The cooling system of claim 1, wherein the liquid jet ejector pump is a steam injector configured to drive the cooling fluid through the secondary loop.

4. The cooling system of claim 1, further comprising:
a vapor passage extending between the at least one capillary loop and the reservoir;
a vapor bypass valve positioned in the vapor passage,
wherein the vapor bypass valve is configured to modulate an amount of the vaporized cooling fluid permitted to the liquid jet ejector pump by directing at least a portion of the vaporized cooling fluid to the reservoir when the vapor bypass valve is in an open position.

5. The cooling system of claim 4, wherein the secondary loop further comprises:
a second heat exchanger fluidly positioned between the liquid jet ejector pump and the reservoir.

6. The cooling system of claim 4, wherein the pump loop further comprises:
a second vapor passage extending from the vapor passage;
a second vapor bypass valve positioned in the second vapor passage; and
a second liquid jet ejector pump,
wherein the second vapor bypass valve is configured to modulate the amount of the vaporized cooling fluid permitted to the second liquid jet ejector pump by directing at least a portion of the vaporized cooling fluid to the reservoir when the second vapor bypass valve is in an open position.

7. The cooling system of claim 1, further comprising:
a reservoir comprising:
a separating member;
a first compartment configured to receive the cooling fluid;
a second compartment configured to receive the cooling fluid, the separating member separating the first compartment from the second compartment,
wherein the separating member is configured to separate the pump loop from the secondary loop, and
wherein the separating member of the reservoir is configured to extend in a predetermined height direction to allow for fluid communication between the second compartment and the first compartment.

8. The cooling system of claim 7, wherein the fluid communication between the second compartment and the first compartment permits for an overflow of the cooling fluid in the secondary loop to travel into the pump loop.

9. The cooling system of claim 6, wherein the secondary loop further comprises:
a plurality of micro-fin structures positioned within a secondary loop passage of the secondary loop, each of the plurality of micro-fin structures configured to reduce a temperature of the cooling fluid within the secondary loop passage.

10. A cooling system comprising:
a heat-generating device; and
a cooler loop assembly comprising:
a manifold thermally coupled to the heat-generating device;
a pump loop having a pump, the pump loop fluidly coupled to the manifold, the pump is configured to move a cooling fluid through the manifold to cool the heat-generating device, a vaporized cooling fluid generated by the cooling of the heat-generating device vented by the manifold; and
a secondary loop having a liquid jet ejector pump, the secondary loop fluidly coupled to the manifold such that the vaporized cooling fluid vented by the manifold is received by the liquid jet ejector pump,
wherein the vaporized cooling fluid is combined with the cooling fluid within the liquid jet ejector pump to circulate the cooling fluid through the secondary loop.

11. The cooling system of claim 10, wherein the cooling fluid within the secondary loop is passively driven by the vaporized cooling fluid generated from the heat-generating device.

12. The cooling system of claim 10, wherein the liquid jet ejector pump is a steam injector configured to drive the cooling fluid through the secondary loop.

13. The cooling system of claim 10, further comprising:
a vapor passage extending between the manifold and the reservoir;
a vapor bypass valve positioned in the vapor passage,
wherein the vapor bypass valve is configured to modulate an amount of the vaporized cooling fluid permitted to the liquid jet ejector pump by directing at least a portion of the vaporized cooling fluid to the reservoir when the vapor bypass valve is in an open position.

14. The cooling system of claim 13, wherein the secondary loop further comprises:
a second heat exchanger fluidly positioned between the liquid jet ejector pump and the reservoir.

15. The cooling system of claim 10, further comprising:
a reservoir comprising:
a separating member configured to separate the cooling fluid into a first compartment and a second compartment, the first compartment configured to receive the cooling fluid and the second compartment configured to receive the cooling fluid.

16. The cooling system of claim 15, wherein the separating member is configured to separate the pump loop from the secondary loop.

17. The cooling system of claim 15, wherein the separating member of the reservoir is configured to extend in a predetermined height direction to allow for fluid communication between the second compartment and the first compartment.

18. The cooling system of claim 17, wherein the fluid communication between the second compartment and the first compartment permits for an overflow of the cooling fluid in the secondary loop to travel into the pump loop.

19. The cooling system of claim 16, wherein the secondary loop further comprises:
a plurality of micro-fin structures positioned within a secondary loop passage of the secondary loop, each of the plurality of micro-fin structures configured to reduce a temperature of the cooling fluid within the secondary loop passage.

20. A method for cooling a heat-generating device comprising the steps of:
pumping a cooling fluid through a pump loop and a capillary loop to cool the heat-generating device, the pump loop having a pump and a heat exchanger, the pump loop fluidly coupled to the capillary loop, the capillary loop having a manifold in which the heat-generating device is thermally coupled thereto, the pump is configured to move the cooling fluid through the manifold to cool the heat-generating device;
venting a vaporized cooling fluid from the capillary loop to a secondary loop having a liquid jet ejector pump; and
driving the cooling fluid through the secondary loop via the liquid jet ejector pump based on an amount of the vaporized cooling fluid vented through the capillary loop provided to the liquid jet ejector pump to circulate the cooling fluid in the secondary loop, the secondary loop is parallel to the pump loop.
